(19) United States
(12) Patent Application Publication
(10) Pub. No.: US 2026/0198334 A1
(43) Pub. Date: Jul. 9, 2026

(54) HIGH RELIABILITY, LOW-COST INTERPOSER

(71) Applicant: ADEIA SEMICONDUCTOR BONDING TECHNOLOGIES INC., San Jose, CA (US)

(72) Inventors: Belgacem Haba, Saratoga, CA (US); Rajesh Katkar, Milpitas, CA (US)

(21) Appl. No.: 19/009,449

(22) Filed: Jan. 3, 2025

(51) Int. Cl. H01L 23/538; H01L 21/48; H01L 23/00; H01L 23/14

(52) U.S. Cl. CPC H10W 70/611; H10W 70/05; H10W 70/698; H10W 90/401; H10W 90/794

(57) ABSTRACT

An interposer assembly may include a substrate, a dielectric layer on a first surface of the substrate, and a first bridge die embedded in the dielectric layer. The substrate can include a plurality of first vias. The first bridge die can include a plurality of bridge die routing layers.

### BACKGROUND OF THE INVENTION

### Field of the Invention

The field relates to microelectronic packaging and assemblies.

### Description of the Related Art

There is a desire to include an increasing number of devices into a semiconductor assembly or package. To accommodate the formation of these complex packages with all of the necessary electrical connections, interposer design has led to the interposer becoming larger and larger with an increased density of interconnects. With the increased size and increased density of interconnects comes a substantial increase in fabrication costs. This has led to the development of alternative structures, such as small bridges. However, the fabrication costs for these small bridges are non-trivial, the packaging process for incorporating the bridges into packages can be complicated, and the resultant packages may have reliability issues. Accordingly, a less costly, high reliability, and scalable interface that can accommodate increasingly complex and dense interconnection within a package is needed.

### BRIEF DESCRIPTION OF THE DRAWINGS

Features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIGS. 1A-1B are schematic cross sections illustrating direct bonding, particularly hybrid bonding, of microelectronic elements.

FIG. 2 is a schematic cross section illustrating an interposer assembly including bridge dies, according to one embodiment.

FIGS. 3A-3F are schematic cross sections illustrating a process for forming a microelectronic package, according to one embodiment.

FIGS. 4A-4G are schematic cross sections illustrating a process for forming a microelectronic package, according to one embodiment.

FIGS. 5A-5E are schematic cross sections illustrating a process for forming a microelectronic package, where three different bridge die mounting configurations are shown according to three embodiments.

FIGS. 6A-6G are schematic cross sections illustrating a process for forming a microelectronic package, according to one embodiment.

FIG. 7A is a schematic cross section illustrating a portion of a bridge die configured for face-down incorporation into a package, according to one embodiment.

FIG. 7B is a schematic cross section illustrating a portion of a package incorporating the bridge die of FIG. 7A face-down.

FIG. 7C is a schematic cross section illustrating a portion of a package incorporating a bridge die face-down, according to one embodiment.

Like reference numbers are used to describe like features throughout the description and drawings.

### DETAILED DESCRIPTION

Although several embodiments, examples, and illustrations are disclosed below, it will be understood by those of ordinary skill in the art that the inventions described herein extend beyond the specifically disclosed embodiments, examples, and illustrations and include other uses of the inventions and obvious modifications and equivalents thereof. Embodiments of the inventions are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the inventions. In addition, embodiments of the inventions can comprise several novel features and no single feature is solely responsible for its desirable attributes or is essential to practicing the inventions herein described.

Advancements in high-performance computing, artificial intelligence, and more, has led to microelectronic assembly packaging becoming increasingly complex. Conventionally, interposers may be used to electrically connect two or more dies together. For example, a silicon (Si) interposer may be used to connect two processors like central processing units (CPUs), graphics processing units (GPUs), neural processing units (NPUs), tensor processing units (TPUs), network switches or one or more processors or network switches and one or more high bandwidth memory (HBM) stacks and/or co-packaged optics, etc. Attempting such connections has resulted in the fabrication of increasingly larger Si interposers. For example, it may be desirable to place HBMs laterally on either side of a GPU, but this arrangement would use a relatively large interposer. Particularly as such interposers become larger to connect more laterally spaced chips (e.g., chiplets) or stacks, the interposer becomes very expensive to fabricate. For example, a 300 mm Si wafer may yield only around 17 interposers of 50 mm×50 mm, or only around 8 interposers of 70 mm×70 mm. Furthermore, as they must connect with dense pads on the chips, the routing for such interposers must be dense (e.g., typically requiring four or more layers of wiring). Although the density may only be needed near the edges of neighboring chips, because wiring formation is a wafer-level process, the entire wafer bears the cost of this multilayer, high density wiring. The fabrication process to ultimately provide this wiring is consequently very expensive, particularly as interposers will typically span areas greater than the typical reticle size of 2500 mm². Indeed, the routing on such large Si interposers can represent a very large portion of the overall interposer cost. Moreover, processing such large, thin interposers can also lead to package reliability challenges.

In response, the industry has begun to see a shift from conventional Si interposers to bridge dies. The bridge dies can be fabricated to have high density routing, and these bridge dies can provide a way to connect neighboring dies through this high-density routing, without requiring such high-density routing to span large interposers. One example is silicon bridge technology (e.g., embedded silicon bridges, etc.). Unfortunately, the current state of processing for these bridge dies is costly and/or the process itself is too complex, such that such bridges are being adopted slowly. For example, some Si bridge dies are embedded within organic materials, which can lead to substantially complex fabrication processes, low yield, higher cost and package reliability issues. Thus, a solution that can reduce fabrication costs while connecting dies with high density pads with high reliability is desired.

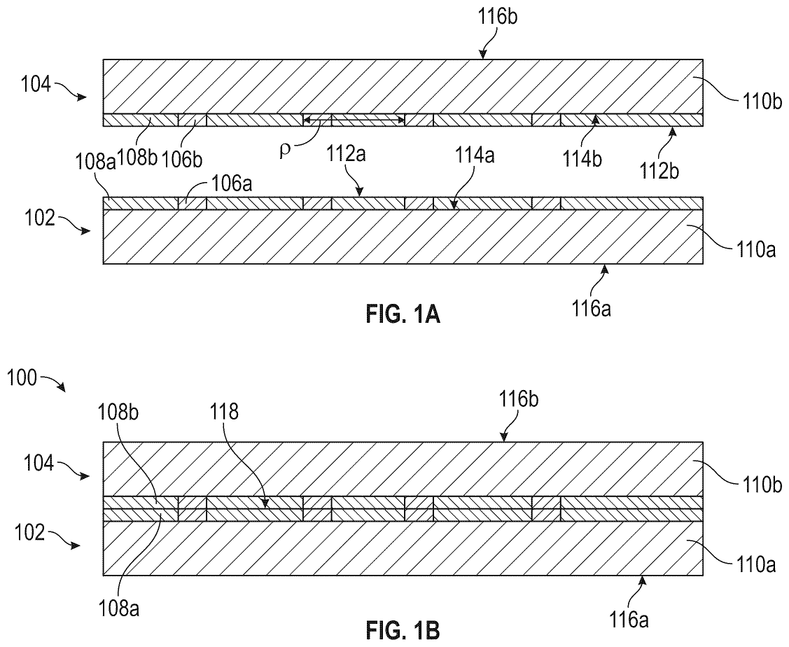

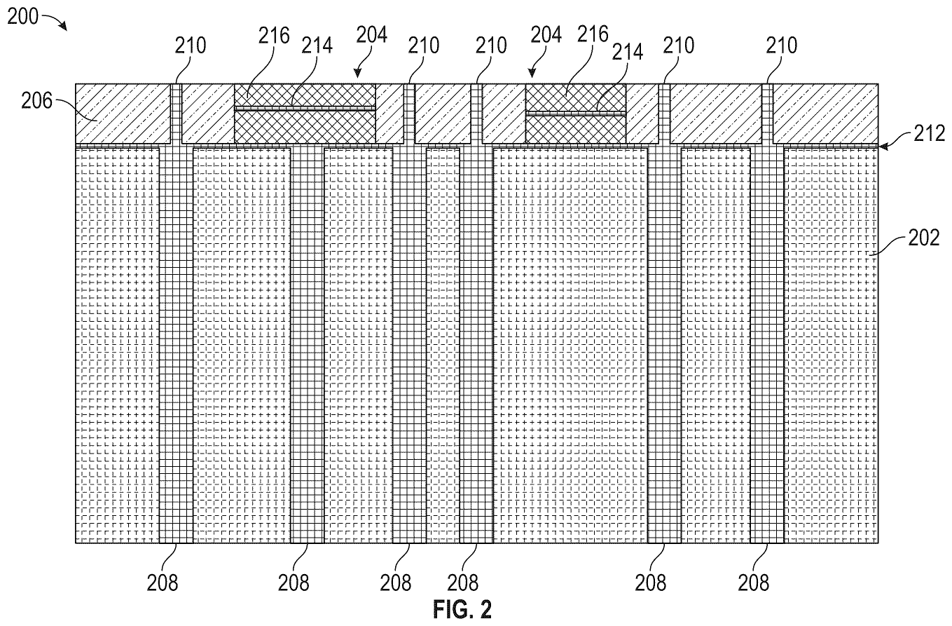

The solutions described herein with respect to FIGS. 2-7C can also benefit from direct bonding, such as uniform direct bonding or hybrid bonding. Such techniques are described below with respect to FIGS. 1A-1B.

### EXAMPLES OF DIRECT BONDING METHODS AND DIRECTLY BONDED STRUCTURES

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. patent application Ser. No. 18/391,173, filed Dec. 20, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Many organic adhesives lack strong chemical or covalent bonds with either element. In such processes, the connections between the elements are weak and/or readily reversed, such as by reheating.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In one example conventional metal bonding process, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry (not shown) can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, one or both of the elements 102, 104 may not include active circuitry, but may instead comprise dummy elements, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises other materials, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate (e.g., a laminate substrate, a ceramic substrate, etc.) or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding layers for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding surfaces 112a, 112b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31,35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially smooths out high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding bonding surfaces, such that a total gap between opposing contacts after dielectric bonding and prior to anneal is less than 15 nm, or less than 10 nm. Because the recess depths for the conductive features 106 a and 106 b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials'melting temperature. In various embodiments, bonds can form at lower temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the surface of the feature, and can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the conductive feature is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly through etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

### EXAMPLE INTERPOSERS INCLUDING ONE OR MORE BRIDGE DIES

As noted above, the interposer (e.g., in 2.5D packaging), has been increasing in size and incorporating denser interconnects. Increasing the size of a Si interposer, especially increasing it to a size exceeding 2× or 3× the reticle size (e.g., approximately greater than 2500mm² ) increases the fabrication costs substantially. Notably, the inclusion of multi-layer high-density conductive lines in the interposer (e.g., the build-up layers) contributes substantially to the cost of such interposers, especially when the utility of multi-layer high density wiring is restricted to limited areas. Costs can be reduced by limiting the multi-layer high density wiring to bridge dies only while low density wiring can occupy the rest of the area of the large footprint relative to the interconnections across a large interposer. However, known techniques for incorporating bridge dies into the package are expensive and prone to reliability issues.

In some embodiments, a mixed structure interposer assembly can be fabricated to reduce the resolution of any build-up layers in the space (or spaces) between the chips to be connected. For example, the interposer assembly can include a substrate, one or more bridge dies attached to the substrate, and a dielectric material that surrounds the bridge dies. Vias can be formed through the substrate to carry signal, and power or ground. The bridge dies can include a high density of conductive lines to interconnect multiple chips (e.g., GPU, HBM, etc.) in a 2.5D or 3D configuration. The bridge dies can be formed in a separate process prior to being disposed on the substrate. In some cases, a wafer can be fabricated to include a plurality of routing layers, and the wafer may be singulated to form the individual bridge dies. The individual bridge dies can then be disposed over a surface of the substrate and embedded in a dielectric material. To facilitate alignment of these reconstituted bridge dies with the chips to be interconnected, RDL can be provided over and/or under the dielectric material and the bridge dies, which can absorb global misalignments. However, such RDL can be coarse and significantly less expensive than wiring for interconnecting with die pads, as is present in the bridge dies. In some cases, limiting the fine, high resolution routing layers to the individual bridge dies can result in fabrication costs that are 1/20th the cost of fabricating the full routing layers of a conventional interposer.

FIG. 2 illustrates an interposer assembly 200 (e.g., an interposer or a mixed structure interposer), according to one embodiment. The interposer assembly 200 can include an interposer substrate 202 and one or more bridge dies 204 embedded in a dielectric layer 206 disposed over the interposer substrate 202. In some embodiments, the interposer substrate 202 is an inorganic substrate, which can be relatively rigid relative to organic materials. In some embodiments, the interposer substrate 202 may be a glass substrate or a glass core substrate (GCS). Glass can be engineered to have a particular coefficient of thermal expansion (CTE). In some embodiments, an interposer substrate 202 that uses glass as its material, can be engineered to provide for CTE matching within the interposer assembly 200. While the large footprint of interposers provides a very limited number of interposer dies fabricated per a standard 300 mm wafer, the synergy between glass substrates including GCS and panel-level packaging (PLP) can provide a significantly higher number of interposer dies per panel. For example, a glass substrate can be obtained from large (e.g., 800 mm×800 mm) panels that are readily available. While the largest standard wafer (300 mm) can accommodate 8 interposer dies of 70×70 mm footprint, an 800×800 mm panel can accommodate 121 dies of similar footprint. Moreover, the usage of glass substrates can expand the supply chain in the industry to substrate or panel manufacturers (e.g., those serving industries such as photovoltaics, TVs, etc., as well as organic substrate manufacturers), helping reduce fabrication costs. In some cases, the interposer substrate 202 may be a Si substrate. In some cases, the interposer substrate 202 may comprise a base material of at least one of glass, Si, quartz, and sapphire. In some cases, the interposer substrate 202 may include a base material of one or more inorganic materials. A plurality of vias 208 (e.g., through substrate vias (TSVs), such as through-glass vias (TGVs)) can be formed in the interposer substrate 202. In some cases, the dielectric layer 206 may include an organic dielectric material (e.g., epoxy mold compound (EMC), resins, polymers (e.g., polyimide (PI), polybenzoxazole (PBO), benzocyclobutene (BCB), etc.)) or an inorganic dielectric material (e.g., silicon oxide, nitride, oxynitride, carbonitride, etc.). In some cases, the dielectric layer 206 can comprise one or more layers of organic or inorganic dielectric materials. Pillars 210 (e.g., posts or vias) can be formed such that they extend through the dielectric layer 206 from the interposer substrate 202. The pillars 210 can be formed from an electrically conductive material. In some cases, the pillars 210 can include one or more of copper, aluminum, nickel, gold, tungsten, etc. In some cases, the pillars 210 can be formed after deposition of the dielectric layer 206 over the interposer substrate 202 through a damascene process (e.g., by forming holes or vias in the dielectric layer 206 and then filling them with a conductive material using a suitable via filling process like electroplating). In some embodiments, the pillars 210 can be formed before the deposition of the dielectric layer 206. For example, the pillars 210 can be formed through a pick-and-place approach, or the pillars 210 can be grown on an upper surface of the interposer substrate 202, such as by plating through a mask or physical vapor deposition through a shadow mask. In some cases, and as shown in FIG. 2, one or more layers of redistribution layer (e.g., RDL 212) may be included between the interposer substrate 202 and the dielectric layer 206. RDL 212 can be included to aid in alignment (e.g., an alignment routing layer) of the bridge dies 204 relative to the interposer substrate 202. In some cases, the interposer assembly 200 does not include the RDL 212.

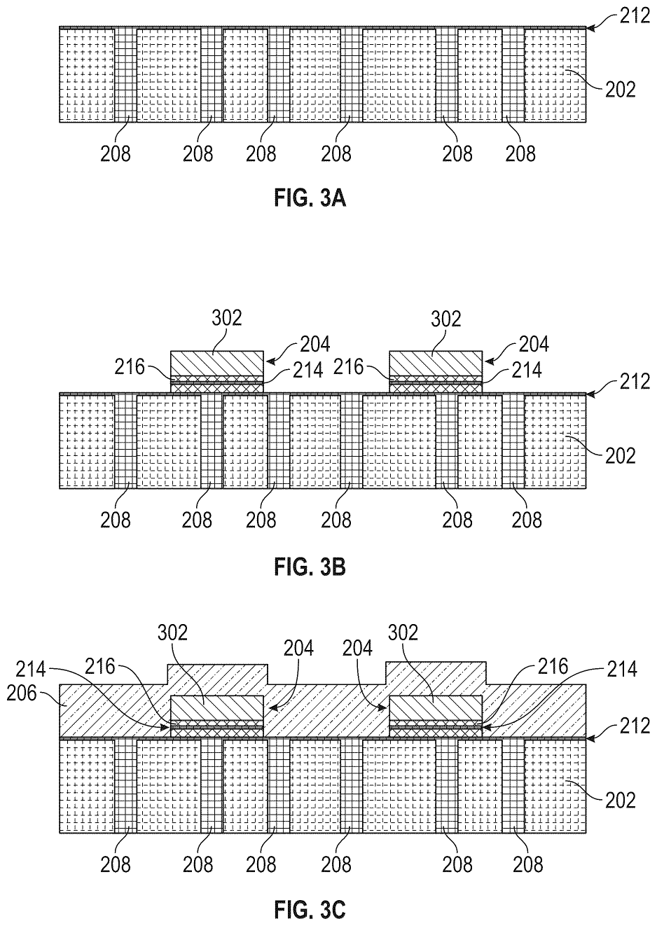

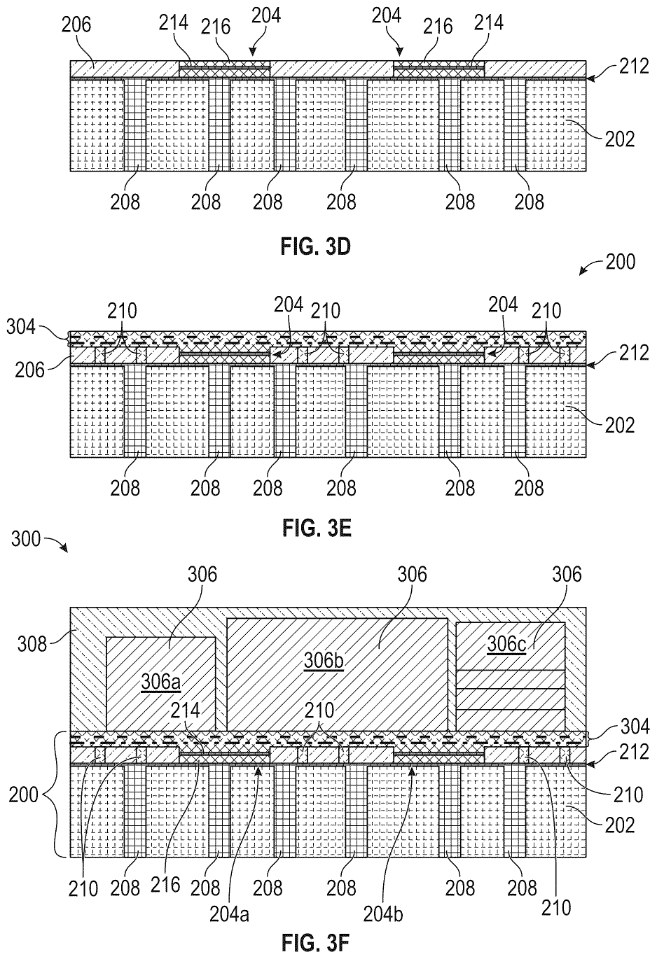

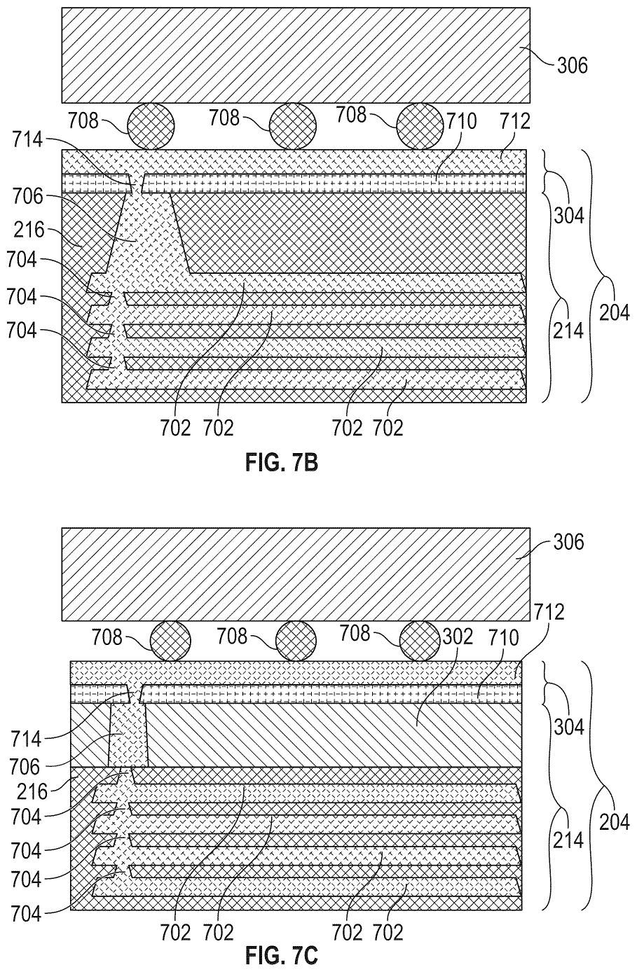

Additionally, and as disclosed with respect to FIGS. 7A-7C, the one or more bridge dies 204 may be fabricated to be high-density wiring bridge dies. For example, a bridge die 204 may include a plurality of routing layers 214. In some cases, four or more layers of high-density wiring may be formed within a bridge die 204. A bridge die 204 can include a bridge die substrate 302 (e.g., FIGS. 3B, 7A-7C), upon which the plurality of routing layers 214 may be formed. The routing layers 214 can be fabricated on the bridge die substrate 302 (e.g., Si) in a dielectric material 216 in the same manner as conventional BEOL layers for integrated circuits in a wafer level process. In some cases, the dielectric material 216 can be an oxide or a nitride.

The bridge die 204 can be fabricated to be used in a face-down or a face-up configuration. As used herein, a face-down configuration refers to a bridge die 204 where the routing layers 214 have been fabricated on a bridge die substrate 302 in a wafer level process, and the bridge die 204 is singulated and flipped upside down and the routing layers 214 are attached to the interposer substrate 202 (e.g., the routing layers 214 are below the bridge die substrate 302 and above the interposer substrate 202). In some face-down configurations, the substrate 302 portion of the bridge die 204 can be removed in fabricating the interposer assembly 200 (see, e.g., FIG. 3D and attendant description). In some cases, the bridge die 204 can be fabricated to be used in a face-up configuration. As used herein, a face-up configuration refers to a bridge die 204 where the routing layers 214 are fabricated on the bridge die substrate 302, and the bridge die substrate 302 of the bridge die 204 is attached to the interposer substrate 202 (e.g., the bridge die substrate 302 is below the routing layers 214 and above the interposer substrate 202).

FIGS. 3A-3F illustrate a process for forming a microelectronic package 300 implementing an interposer assembly 200, according to some embodiments. In particular, the illustrated process shows a face-down configuration of the one or more bridge dies 204 with respect to the interposer substrate 202.

As shown in FIG. 3A, an interposer substrate 202 is provided and a plurality of vias 208 (e.g., TSVs, such as TGVs) can be formed in the interposer substrate 202. In some embodiments, an interposer substrate 202 can be processed as a wafer or a panel. Although not shown, in some cases, the plurality of vias 208 may include blind vias formed within the interposer substrate 202, and the interposer substrate 202 can be subsequently thinned to expose the ends of the plurality of vias 208 on opposing surfaces of the interposer substrate 202. Further, although FIG. 3A shows the interposer substrate 202 as including an RDL 212 on a surface (e.g., an upper surface) of the base material of the interposer substrate 202, in some cases, the RDL 212 may not be included. In some embodiments, the RDL 212 may be formed on a bottom surface of the interposer substrate 202. In some embodiments, the interposer substrate 202 is an inorganic substrate. In some cases, the interposer substrate 202 can include a base material of one or more inorganic materials (e.g., glass, Si, quartz, sapphire, etc.). In some cases, the interposer substrate 202 is a glass substrate. In some embodiments, the interposer substrate 202 can comprise an organic substrate (e.g., PCB, EMC, resin, PI, PBO, BCB, etc.).

In FIG. 3B, one or more bridge dies 204 can be attached to the upper surface of the interposer substrate 202, in the illustrated embodiment to the RDL 212 of the interposer substrate 202. The RDL 212 is coarse (lower resolution, or larger feature sizes) compared to the routing layers 214 of the bridge dies 204. The one or more bridge dies 204 can be formed to be used in a face-down configuration such that the bridge die substrate 302 is located on an upper surface of the bridge die 204. In some embodiments, the one or more bridge dies 204 can be attached to the interposer substrate 202 with an adhesive. In some embodiments, the one or more bridge dies 204 can be directly bonded to the interposer substrate 202. In cases where the interposer substrate 202 is devoid of the RDL 212, the one or more bridge dies 204 can be directly bonded to the base material (e.g., glass) of the interposer substrate 202 or to a dielectric bonding layer thereover. Where the interposer substrate 202 includes RDL 212, the bridge dies 204 can be flip chip attached to the RDL 212, or can be hybrid bonded as described herein. For example, a bridge die 204 may have a surface that comprises a first dielectric and a first conductive feature and the interposer substrate 202 may also have a surface comprising a second dielectric and a second conductive feature (e.g., an end portion corresponding to a via 208). The first dielectric and the second dielectric can be directly bonded to form a dielectric-to-dielectric bond, and the first conductive feature and the second conductive feature can be directly bonded to form a metal-to-metal bond. In some embodiments, the one or more bridge dies 204 can be bonded to the interposer substrate 202 using an adhesive (e.g., die attach material).

As shown in FIG. 3C, a dielectric material 206 can be deposited over the one or more bridge dies 204 and the interposer substrate 202. The dielectric material 206 can include an inorganic dielectric (e.g., silicon oxide, nitride, oxynitride, carbonitride, etc.) or organic dielectric (e.g., epoxy mold compound (EMC), resins, polymers (e.g., polyimide (PI), polybenzoxazole (PBO), benzocyclobutene (BCB), etc.)).

In FIG. 3D, the assembly can be thinned or planarized. In some embodiments, the substrate 202 may be attached to a carrier prior to grinding (or before attaching 204 in FIG. 3B). The dielectric material 206 is thinned, and the upper surface of the dielectric material 206 can be made coplanar with the upper surface of the one or more bridge dies 204. As FIG. 3D illustrates, some or all of the bridge die substrate 302 material can be removed from a bridge die 204 in the course of planarizing the dielectric material 206. The removal of the bulk material (e.g., the bridge die substrate 302, or bulk Si) results in leaving only the routing layers 214 of the bridge dies 204 in the interposer assembly 200 for the purpose of keeping a thickness of the bridge die relatively thin. In some embodiments, the planarizing step can yield a final effective bridge die thickness of less than 20 μm, less than 10 μm, or less than 5 μm. In some embodiments, the thinned bridge dies 204 can include some thinned substrate 302 material.

FIG. 3E shows the formation of pillars 210 (e.g., vias or posts) in the dielectric layer 206. For example, the pillars 210 can be formed by etching vias in the dielectric layer 206 and subsequently filled with a conductive material in a damascene process. A routing layer 304 (e.g., an RDL) can be formed afterwards over the dielectric layer 206 including the one or more bridge dies 204 and the pillars 210. Beneficially, the routing layer 304 can absorb global misalignments. In some cases, the alignment to an integrated device die (or an integrated circuit element) may not be less than 10 μm. In some cases, the technology node or line width of the routing layers 214 of the bridge dies 204 can be finer than the technology node or resolution for the RDL 212 (if present) or the routing layer 304. For example, the pitch of contact pads for the bridge dies 204 can be less than 100% or less than 50% the contact pitch of the RDL 212 (if present) or the routing layer 304. For example, the contact pitch of the routing layers 214 can be between 5% and 40% of the contact pitch of the RDL 212 or the routing layer 304, or between 10% and 30%. In some embodiments, the interposer assembly 200 may not include the routing layer 304. In some embodiments, routing between the bridge dies 204 and the routing layer 304 is conducted through the RDL 212 of the interposer substrate 202 and the pillars 210. In some embodiments, the routing layer 304 can additionally or alternatively directly connect to the interconnects in the bridge dies 204 through the backside (upper surface) of the bridge dies, as will be better understood from description of FIGS. 7A-7C below.

FIG. 3F shows that once the interposer assembly 200 has been fabricated, integrated device dies 306 (e.g., a first integrated circuit element 306a, second integrated circuit element 306b, integrated circuit element stack 306c), can be attached to the interposer assembly 200. The integrated device dies 306 can be attached using techniques such as flip-chip bonding, thermocompression bonding, direct bonding, hybrid bonding, etc. In some cases implementing hybrid bonding for example, the routing layer 304 has a bonding surface comprising a dielectric and conductive features, which can be directly bonded to a surface of one or more integrated device dies 306 (e.g., FIG. 3F), such that the dielectric is directly bonded to complementary dielectrics of the integrated device dies 306 and the conductive features are directly bonded to complementary conductive features of the integrated device dies 306.

As shown in FIG. 3F, the first integrated circuit element 306a can be electrically connected to second integrated circuit element 306b through one bridge die 204a, and the second integrated circuit element 306b can be electrically connected to the integrated circuit element stack 306c through a second bridge die 204b. Following the attachment of the integrated device dies 306, a dielectric 308 may be provided that encapsulates and protects the integrated circuit elements 306. In some cases, the dielectric 308 comprises an organic dielectric material (e.g., epoxy mold compound (EMC), resins, polymers (e.g., polyimide (PI), polybenzoxazole (PBO), benzocyclobutene (BCB), etc.)) or an inorganic dielectric material (e.g., silicon oxide, nitride, oxynitride, carbonitride, etc.). In some embodiments, the integrated circuit element 306 can include a die stack (e.g., the integrated circuit element stack 306c), such as an HBM stack. Beneficially, with the face-down configuration of the bridge dies 204 in the illustrated microelectronic package 300, any effective bridge die thickness can be implemented, and the final thickness can be minimized through a grinding or polishing process. Further, although not shown, in some embodiments, additional components or elements such as passive components (e.g., capacitors, dummy silicon, spacers, etc.) and heat dissipation (e.g., cooling) or heating elements may be included within the microelectronic package 300. For example, in addition to the inclusion of pillars 210 between the one or more bridge dies 204, thermally conductive pathways could also be provided within these spaces or regions between individual bridge dies to aid in thermal regulation of the microelectronic package 300.

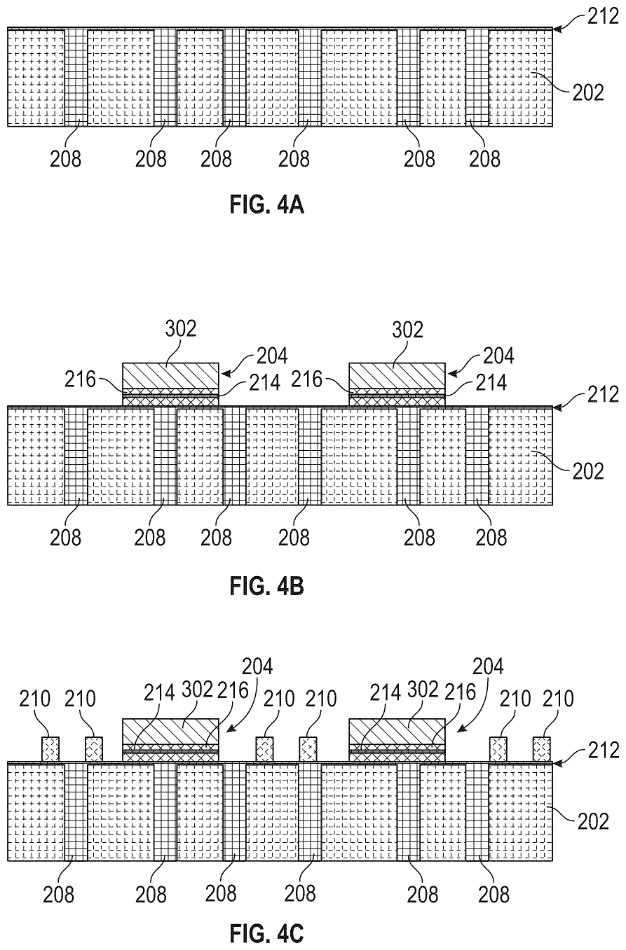

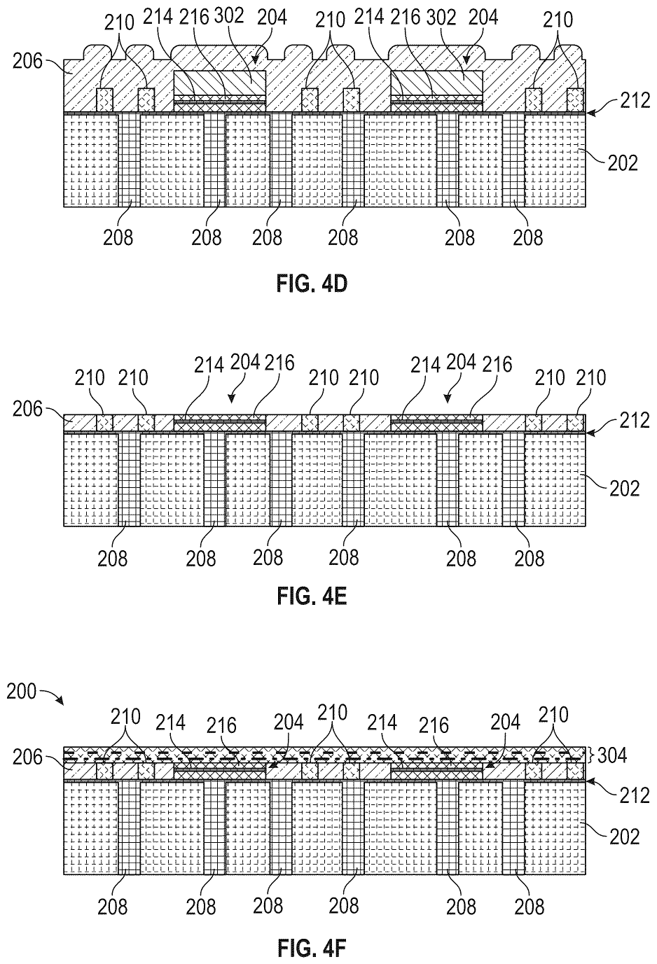

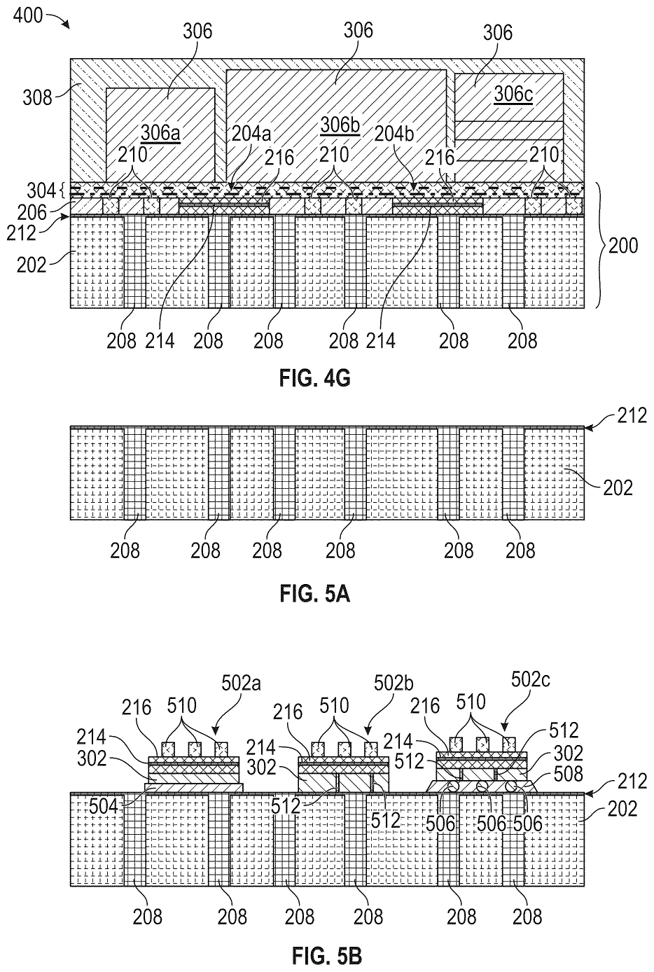

FIGS. 4A-4G illustrate a process for forming a microelectronic package 400 implementing an interposer assembly 200, according to some embodiments. The illustrated process shows another instance of a face-down configuration of the one or more bridge dies 204 with respect to the interposer substrate 202. Unless otherwise noted, the components of FIGS. 4A-4G are the same as or generally similar to the components illustrated in FIGS. 3A-3F. Unlike in FIGS. 3A-3F where the pillars 210 are formed after the deposition of the dielectric layer 206, FIGS. 4A-4G show an embodiment where the pillars 210 are formed before the deposition of the dielectric layer 206. Forming the pillars 210 before the deposition of the dielectric layer 206 may be beneficial in embodiments implementing thick bridge dies (e.g., >50 μm), or in embodiments where the dielectric layer 206 comprises an organic material.

In FIG. 4A, an interposer substrate 202 (e.g., glass, GCS, Si, quartz, sapphire, etc.) is provided. The interposer substrate 202 can include an RDL 212 on an upper surface of the interposer substrate 202 and a plurality of vias 208 through the interposer substrate 202. As with FIG. 3A, in some embodiments the RDL 212 can be omitted.

In FIG. 4B, one or more bridge dies 204 can be attached to the upper surface of the interposer substrate 202. The attachment can be through direct bonding, particularly hybrid bonding if the RDL 212 is included, or through the use of an adhesive.

FIG. 4C illustrates the fabrication of the pillars 210 on the upper surface of the interposer substrate 202 before the deposition of the dielectric material 206. In some embodiments, if the one or more bridge dies 204 are attached to the interposer substrate 202 through a direct bonding process, then the one or more bridge dies 204 are direct bonded prior to the formation of the pillars 210. In some embodiments, if the one or more bridge dies 204 are attached to the interposer substrate 202 through the usage of an adhesive (e.g., laminate, die attach material, resin, etc.), then the pillars 210 can be formed on the interposer substrate 202 before or after the one or more bridge dies 204 are attached. In some embodiments, the pillars 210 can be formed using fabrication steps including applying a resist, developing and patterning the resist, plating the pillars 210 (e.g., copper pillars or other electrically conductive pillars) on the RDL 212 (or if no RDL 212 is used, then plating the pillars 210 directly on the interposer substrate 202 (e.g., glass), particularly in contact with the TSVs 208), and then removing the resist. In other embodiments, the pillars 210 can be picked and placed. In some other embodiments, free standing wire bonds (e.g., bond via arrays (BVA)) can also be formed.

As shown in FIG. 4D, an organic or inorganic dielectric is deposited over the one or more bridge dies 204 and the pillars 210. Then, in FIG. 4E, the dielectric material and the bridge die substrate 302 can be thinned or planarized. In some cases, some of the bridge die substrate 302 is removed. In some cases, all of the bridge die substrate 302 is removed. After the thinning step, the final effective bridge die thickness can be less than 5 μm.

FIG. 4F illustrates the fabrication of a routing layer 304 over the dielectric layer 206 comprising the pillars 210 and the one or more bridge dies 204. The routing layer 304 can function to absorb global misalignments. In some cases, the alignment tolerance of the interposer assembly 200 to integrated device dies 306 is greater than or equal to about 10 um. As noted with respect to FIG. 3E, the routing layers 214 of the bridge dies 204 can electrically communicate with the routing layer 304 through the front side (lower surface) of the bridge dies 204, by way of the RDL 212 and pillars 210, and/or through the back side (upper surface) of the bridge dies 204.

FIG. 4G shows that integrated device dies 306 can be attached to the routing layer 304, and a mold 308 can be formed over the integrated device dies 306 and the exposed routing layer 304. The integrated device dies 306 can be attached using a flip chip process, thermocompression bonding, or direct bonding (e.g., hybrid bonding). Further, as illustrated, the first integrated circuit element 306a can be electrically connected to the second integrated circuit element 306b through the first bridge die 204a and the second integrated circuit element 306b can be electrically connected to the integrated circuit element stack 306c through the second bridge die 204b.

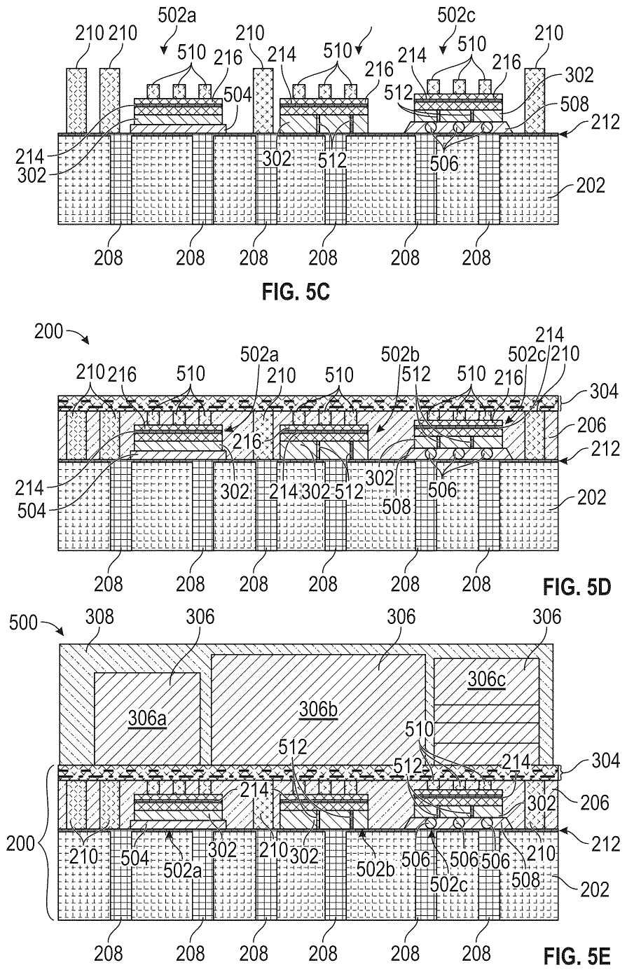

FIGS. 5A-5E illustrate a process for forming a microelectronic package 500 implementing an interposer assembly 200, according to some embodiments. The illustrated process shows three different face-up configurations of bridge dies 502a-502c with respect to the interposer substrate 202 to represent three different embodiments.

In FIG. 5A, an interposer substrate 202 is provided. In some embodiments, and as illustrated, the interposer substrate 202 can include an RDL 212 on an upper surface of the interposer substrate 202 and a plurality of vias 208 through the interposer substrate 202. In some cases, the bridge die routing layers 214 can be finer than the RDL 212 if present. As with FIGS. 3A and 4A, in some embodiments the RDL 212 can be omitted. In some embodiments, the interposer substrate 202 is an inorganic substrate. In some cases, the interposer substrate 202 can include a base material of one or more inorganic materials (e.g., glass, Si, quartz, sapphire, etc.). In some cases, the interposer substrate 202 is a glass substrate.

FIG. 5B shows that one or more bridge dies 502a-502c can be attached to the upper surface of the interposer substrate 202. Because the one or more bridge dies 204 are configured for a face-up implementation, the bridge die substrate 302 is above the interposer substrate 202 and below the bridge die routing layers 214 and their dielectric material 216 (e.g., the bridge die substrate 302 is between the interposer substrate 202 and the dielectric material 216 of the routing layers 214). Several different attachment approaches may be used to attach the one or more bridge dies 204 to the interposer substrate 202. For example, a bridge die 502a can be attached with an adhesive 504 (e.g., die attach, resin, polymer, etc.). A bridge die 502b can be attached to the RDL 212 of the interposer substrate 202 through direct bonding, particularly hybrid bonding. In another example, a bridge die 502c can be attached to the RDL 212 of the interposer substrate 202 using a flip-chip mounting approach employing solder bumps 506. Underfill 508 can surround the solder bumps 506, filling the gap between the bridge die substrate 302 and the upper surface of the interposer substrate 202. Bridge die pillars 510 (e.g., copper pillars or posts) can be formed on an upper surface of the one or more bridge dies 204.

For embodiments employing electrical connection between the back side (lower surface) of the bridge dies 502b, 502c and the RDL 212, through substrate vias (TSVs 512) can be formed through the bridge die substrate 302. The TSVs 512 provide an electrical connection from the interposer substrate 202 through the bridge die pillars 510. The bridge die 502c shows the electrical pathway as extending from the plurality of vias 208 in the interposer substrate 202 to the RDL 212 formed on the upper surface of the interposer substrate 202, to the solder bumps 506, through the TSVs 512 in the bridge die substrate 302, to the bridge die routing layers 214, and through the bridge die pillars 510.

FIG. 5C illustrates the fabrication of the pillars 210 on the upper surface of the interposer substrate 202 before the deposition of the dielectric material 206. In some embodiments, if the one or more bridge dies 204 are attached to the interposer substrate 202 through a direct bonding process, then the one or more bridge dies 204 are direct bonded prior to the formation of the pillars 210. In some embodiments, if the one or more bridge dies 204 are attached to the interposer substrate 202 through the usage of an adhesive, then the pillars 210 can be formed on the interposer substrate 202 before or after the one or more bridge dies 204 are attached. As described with respect to FIGS. 4D and 4E, after the pillars 210 have been formed over the interposer substrate 202, the dielectric material 206 can be deposited over the one or more bridge dies 204, the pillars 210, and the bridge die pillars 510. Following the dielectric deposition, the structure can be thinned or planarized such that the upper end portions of the pillars 210 and the bridge die pillars 510 are coplanar with an upper surface of planarized layer of the dielectric material 206.

FIG. 5D illustrates the fabrication of the routing layer 304 over the dielectric material 206 (which embeds the pillars 210 and the one or more bridge dies 204). As described herein, the routing layer 304 can function to absorb global misalignments when attaching integrated circuit element 306 to the interposer assembly 200. In some cases, the technology node or line widths of the routing layers 214 of the bridge dies 204 can be finer than that of the RDL 212 (if present) or routing layer 304. For example, the pitch of contacts to the routing layers 214 of the bridge dies 204 can be less than 100% or less than 50% the contact pitch of the RDL 212 (if present) or the contact pitch of the routing layer 304. For example, the contact pitch of the routing layers 214 can be between 5% and 40% of the contact pitch of the RDL 212 or the routing layer 304, or between 10% and 30%. The routing layer 304 provides routing and electrical connections with the pillars 210 and the bridge die pillars 510.

FIG. 5E shows that integrated device dies 306 can be attached to the routing layer 304, and a mold 308 can be formed over the integrated device dies 306 and the exposed routing layer 304. The integrated device dies 306 can be attached using a flip chip process, thermocompression bonding, or direct bonding (e.g., hybrid bonding). Further, as illustrated, the first integrated circuit element 306a can be electrically connected to the second integrated circuit element 306b through the first bridge die 204a and the second integrated circuit element 306b can be electrically connected to an integrated circuit element stack 306c through the second bridge die 204b.

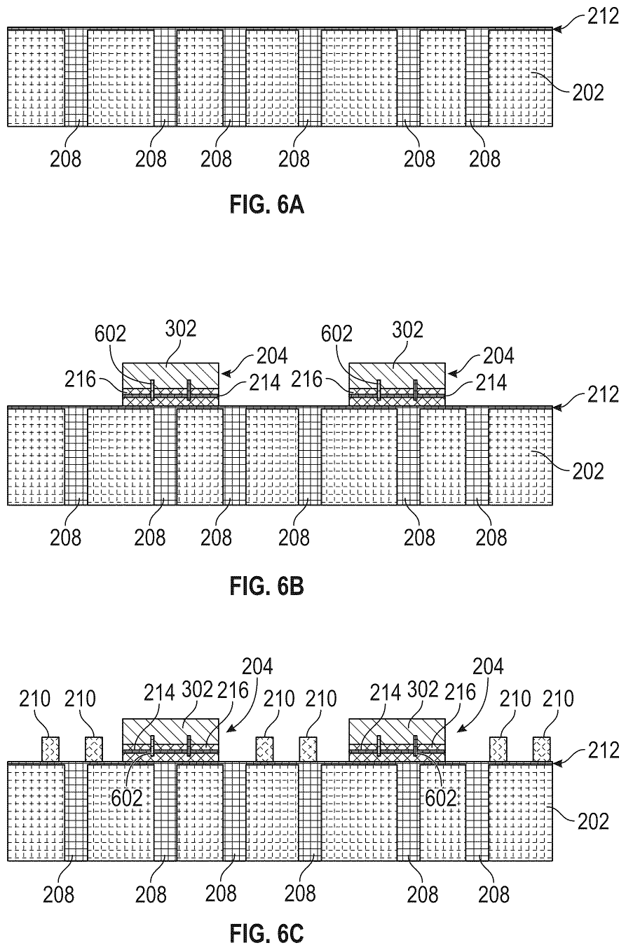

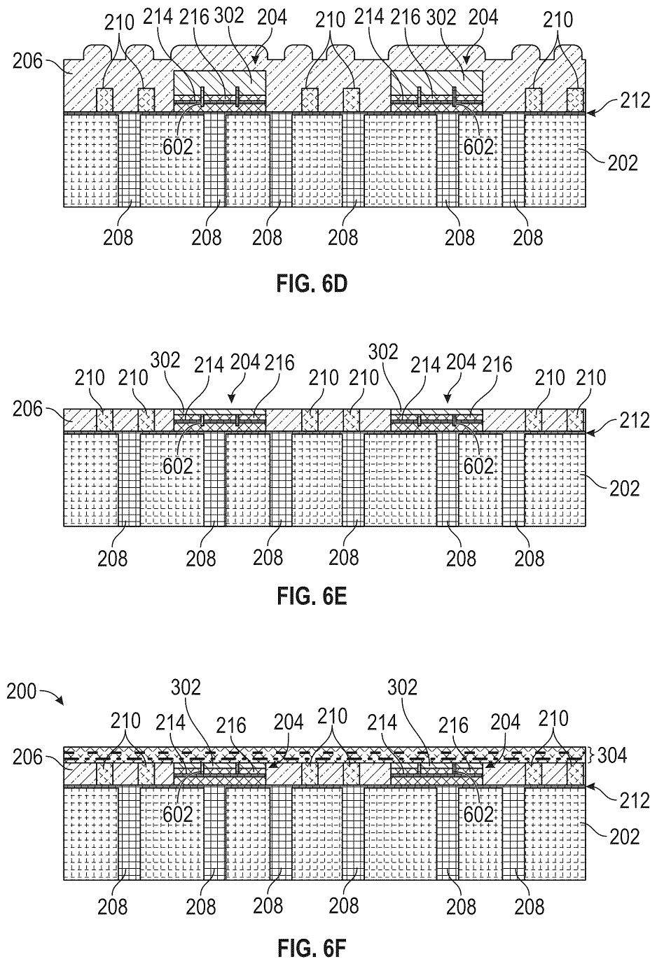

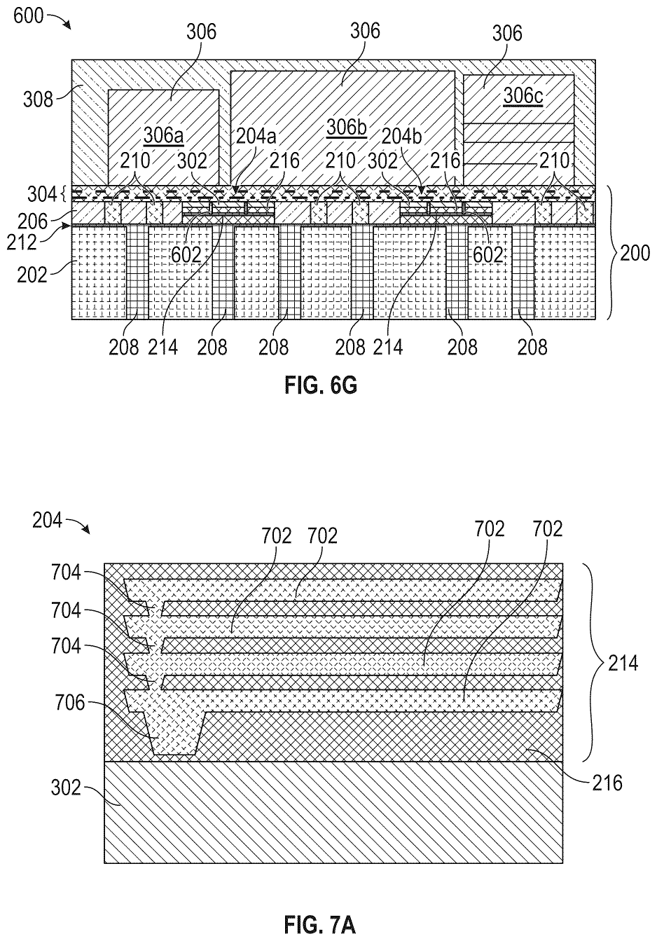

FIGS. 6A-6G illustrate a process for forming a microelectronic package 600 implementing an interposer assembly 200, according to some embodiments. The illustrated process shows another instance of a face-down configuration of the one or more bridge dies 204 with respect to the interposer substrate 202. Unless otherwise noted, the components of FIGS. 6A-6G are the same as or generally similar to the components illustrated in FIGS. 4A-4G. Unlike in FIGS. 4A-4G where the bridge die substrate 302 is completely removed from the one or more bridge dies 204, FIGS. 6A-6G show a process where some of the bridge die substrate 302 remains following a thinning or planarizing step, and the bridge dies 204 include TSVs.

In FIG. 6A, the interposer substrate 202 is provided. The interposer substrate 202 can include an RDL 212 on an upper surface of the interposer substrate 202 and a plurality of vias 208 through the interposer substrate 202. As noted with respect to prior embodiments, the RDL 212 can be omitted in some cases. Further as noted with respect to prior embodiments, the interposer substrate 202 can be an inorganic substrate. In some cases, the interposer substrate 202 can include a base material of one or more inorganic materials (e.g., glass, Si, quartz, sapphire, etc.). In some cases, the interposer substrate 202 is a glass substrate.

FIG. 6B shows that one or more bridge dies 204 can be attached to the upper surface of the interposer substrate 202. The attachment can be through direct bonding (e.g., hybrid bonding if the RDL 212 is present) or an adhesive. The one or more bridge dies 204 can include vias 602 (e.g., TSVs) that extend at least partially through the bridge die substrate 302. As described herein, the pillars 210 can be formed before or after the deposition of the dielectric material 206. FIG. 6C illustrates the fabrication of the pillars 210 on the upper surface of the interposer substrate 202 before the deposition of the dielectric material 206.

As shown in FIG. 6D, the dielectric material 206, which can be an organic or inorganic dielectric, is deposited over the one or more bridge dies 204 and the pillars 210. Then, in FIG. 6E, the dielectric material 206 and the bridge die substrate 302 can be thinned or planarized such that the ends of the vias 602 are exposed and approximately coplanar with the dielectric layer 206 and the pillars 210. The inclusion of the vias 602 can provide additional flexibility with electrical routing in the interposer assembly 200. After the thinning step, the final effective bridge die 204 thickness can be less than 5 μm. As shown in FIG. 6F a routing layer 304 can be fabricated over the dielectric layer 206. The routing layer 304 can function to absorb global misalignments. In some cases, a contact pitch of the routing layers 214 of the bridge dies 204 can be less than 100% or less than 50% the contact pitch of the RDL 212 (if present) or the routing layer 304. For example, the contact pitch of the routing layers 214 can be between 5% and 40% of the contact pitch of the RDL 212 or the routing layer 304, or between 10% and 30%. In some cases, the alignment tolerance of the interposer assembly 200 to integrated circuit element 306 is greater than or equal to about 10 μm. Additionally, the routing layer 304 facilitates an electrical connection with the vias 602 and the pillars 210.

FIG. 6G shows that integrated device dies 306 can be attached to the routing layer 304, and a mold 308 can be formed over the integrated device dies 306 and the exposed routing layer 304. The integrated device dies 306 can be attached using a flip chip process, thermocompression bonding, or direct bonding (e.g., hybrid bonding). Further, as illustrated, the first integrated circuit element 306a can be electrically connected to the second integrated circuit element 306b through the first bridge die 204a and the second integrated circuit element 306b can be electrically connected to an integrated circuit element stack 306c through the second bridge die 204b.

FIGS. 7A-7C illustrate embodiments of a bridge die 204 that can be fabricated for a face-down implementation in the interposer assembly 200. For simplicity, the interposer substrate 202 has been omitted from FIGS. 7A-7C.

As shown in FIG. 7A, a bridge die 204 can be formed by fabricating the routing layers 214 over the bridge die substrate 302. In some cases, the bridge die 204 can be formed as a result of singulating a wafer in which routing layers have been fabricated. In some cases, the bridge die substrate 302 can be a silicon substrate. In some cases, the routing layers 214 are formed on the silicon substrate by fabricating electrically conductive elements in dielectric material 216, such as an oxide or a nitride. For example, a plurality of patterned electrically conductive layers 702 parallel to the surface of the silicon substrate. In some cases, two to four metallization layers can be fabricated. In some cases, four to eight metallization layers can be fabricated. In some cases, more than eight layers can be fabricated. Individual conductive layers of the plurality of electrically conductive layers 702 can be electrically connected through the formation of electrically conductive vertical connections 704.

A tall pillar or a stud 706 can be fabricated prior to the formation of the routing layers 214, between the lowest conductive layer 702 and the bridge die substrate 302. In some cases, the stud 706 can be about 50% to 400% taller and about 100% to 1000% greater surface area than the electrically conductive vertical connections 704. In some cases, the electrically conductive vertical connections 704 can have a height of approximately 1 μm or less and a diameter less than 0.5 μm. For example, the electrically conductive vertical connections 704 can have a height between 0.5 μm and 1 μm. In some cases, the stud 706 can have a height of approximately 0.2 μm to 5 μm and a diameter between approximately 0.2 μm and 3 μm. In some cases, the stud 706 can have an initial height between approximately 0.5 μm and 5 μm. In some cases, the stud 706 can have a final height between approximately 0.2 μm and 2 μm. For example, the stud 706 can have an initial height and be polished or ground to obtain a final height such that the initial height is approximately 20% to 50% taller than the final height. The stud 706 can provide a relatively large connection for the routing layer 304 to connect to at the back side (upper surface) of the bridge die with relative high alignment tolerance, and also provides a greater thickness such that later thinning or planarizing steps can proceed to make the upper surfaces of multiple adjacent bridge dies 204 coplanar with one another, without the concern of thinning the bridge dies too far and possibly removing portions of the routing layers 214.

FIG. 7B shows the bridge die 204 of FIG. 7A attached to an integrated device die 306 (e.g., a processor or memory die or chip). The illustrated bridge die 204 comprises four routing layers. The bridge die 204 can be flipped upside down and thinned to completely remove the bridge die substrate 302 and expose the stud 706. The routing layer 304 is formed over and in electrical connection with the bridge die 204. The routing layer 304 includes a thin dielectric layer 710, a via 714 therethrough, and an overlying patterned metal layer 712. In some embodiments, the thin dielectric layer 710 includes an organic dielectric material, such as polyimide (PI), polybenzoxazole (PBO), or benzocyclobutene (BCB). In some embodiments, the thin dielectric layer 710 includes an inorganic dielectric material, such as a silicon oxide, silicon nitride, etc. After deposition and patterning of the thin dielectric layer 710, a via 714 can be fabricated in the thin dielectric layer 710 to provide an electrical pathway to the stud 706. The patterned metal layer RDL 712 can be formed over or within the thin dielectric layer 710, such as by damascene processing. A first integrated circuit element 306a can subsequently be attached to the RDL 712 using a solder attachment or hybrid bonding. FIG. 7B illustrates the attachment of an integrated device dies 306 to the bridge die 204 using solder balls 708. The orientation of the via 714 of the routing layer 304, with a wider upper surface compared to the lower surface, is opposite that of the stud 706 and vias 704 of the bridge die routing 214.

The structure of FIG. 7B can be employed in the embodiments of FIGS. 3A-4G where direct connection is desired between the back side (upper surface) of the bridge dies 204 and the overlying routing layer 304.

FIG. 7C shows another embodiment where the bridge die 204 is attached to an integrated circuit element 306 and includes four routing layers. Unlike FIG. 7B, in FIG. 7C, the stud 706 comprises a TSV formed in the bridge die substrate 302 instead of the dielectric material 216 of the bridge die 204. In this embodiment, the bridge die substrate 302 is not completely removed in a planarizing step. Although not shown, additional TSVs can be included to extend from the routing layers 214 through the bridge die substrate 302.

Retaining a portion of the bridge die substrate 302, as shown in FIG. 7C, can allow for a more facile fabrication processing step. Some standard TSV reveal processes occur from a back side. As a result, the retention of a portion of the bridge die substrate 302 allows for the implementation of a stud 706 (FIG. 7C) that can be taller than the stud 706 illustrated in FIGS. 7A and 7B, which can make it easier to process in a subsequent polishing or grinding step as part of the TSV reveal process. As with FIG. 7B, the orientation of the via 714 of the routing layer 304, with a wider upper surface compared to the lower surface, is opposite that of the stud 706 and vias 704 of the bridge die routing 214. In some embodiments, a bonding layer (including one or more dielectric layers) may be formed after the TSV reveal process to enable hybrid bonding.

The structure of FIG. 7C can be employed in the embodiment of FIGS. 6A-6G, providing TSVs in the bridge die 204 for direct connection between the back side (upper surface) of the bridge dies 204 and the overlying routing layer 304.

The electrically conductive vertical connections 704 and the stud 706 comprise sidewalls. In some embodiments, the sidewalls can be orthogonal (or substantially orthogonal) to a length of the plurality of patterned electrically conductive layers 702. In some embodiments, the sidewalls can be sloped. The slope of the sidewalls can indicate the direction of build-up of the routing layers 214 on the bridge die substrate 302. In some cases, the slope provides information pertaining to the direction of an etching process. Thus, as noted, the orientation of the via 714 of the routing layer 304, with a wider upper surface compared to the lower surface, can be opposite that of the stud 706 and vias 704 of the bridge die routing 214.

A mixed-structure interposer assembly is described herein. The mixed-structure interposer assembly can include a relatively rigid interposer substrate, such as a silicon or a glass substrate, with vias extending through the substrate. One or more bridge dies can be separately formed and subsequently attached to the interposer substrate (e.g., reconstituted bridge dies). The bridge dies can include a plurality of relatively fine routing layers to allow for the electrical interconnection of two or more integrated circuit elements. The mixed-structure interposer assembly is advantageous in that it allows for a lower cost fabrication process because it can decouple the high-cost routing layers from interposer routing layers, which can be comparatively coarser and less costly. Further, the mixed-structure interposer assembly described herein can preserve the global alignment with respect to integrated circuit elements, and it offers a level of reliability that may not be achievable with organic substrates. Additionally, the ability to utilize a glass substrate in the mixed-structure interposer assembly, allows assembly and routing to use technology nodes available to packaging houses, and only the bridge dies employ the higher resolution technologies typically employed by IC fabrication facilities.

In some aspects, the techniques described herein relate to an interposer, including an inorganic substrate, a dielectric layer on a first surface of the inorganic substrate, and a first bridge die embedded in the dielectric layer. The first bridge die includes a plurality of bridge die routing layers, and the inorganic substrate includes a plurality of first vias.

In some embodiments, the first bridge die is directly bonded over the inorganic substrate. In some embodiments, the first bridge die is hybrid bonded over the inorganic substrate. In some embodiments, a routing layer is disposed on the first surface of the inorganic substrate and below the first bridge die. In some embodiments, the inorganic substrate includes a glass base material. In some embodiments, a second bridge die is included and embedded in the dielectric layer. In some embodiments, the dielectric layer includes an inorganic dielectric. In some embodiments, the dielectric layer includes an organic dielectric. In some embodiments, a routing layer is included over the dielectric layer and the first bridge die. In some embodiments, the routing layer includes a bonding surface to attach the interposer to a die. The bonding surface can be prepared for at least one of a flip chip bond, a thermocompression bond, or a hybrid bond. In some embodiments, the routing layer includes a bonding surface to hybrid bond the interposer to a die. In some embodiments, the dielectric layer includes a plurality of second vias. In some embodiments, the dielectric layer includes a plurality of damascene second vias. In some embodiments, a bonding surface is included on an upper surface of the interposer. The upper surface can include the dielectric layer. In some embodiments, the first bridge die includes a silicon substrate, where the plurality of bridge die routing layers is between the silicon substrate and the inorganic substrate. In some embodiments, the first bridge die includes a silicon substrate. The silicon substrate can be below the plurality of bridge die routing layers and above the inorganic substrate. In some embodiments, the first bridge die includes a plurality of through substrate vias.

In some aspects, the techniques described herein relate to an interposer, including a substrate, a dielectric layer on a first surface of the substrate, and a first bridge die embedded in the dielectric layer. The first bridge die can include a plurality of bridge die routing layers, and the first bridge die can be directly bonded over the substrate. The substrate can include a plurality of first vias.

In some embodiments, the substrate includes an inorganic substrate. In some embodiments, the first bridge die is hybrid bonded to the first surface of the inorganic substrate. In some embodiments, the inorganic substrate includes a routing layer, where the routing layer defines at least in part the first surface of the inorganic substrate. In some embodiments, the inorganic substrate includes a glass base material. In some embodiments, the first bridge die includes a silicon substrate, where the plurality of bridge die routing layers is between the silicon substrate and the inorganic substrate. In some embodiments, the first bridge die includes a silicon substrate, where the silicon substrate is below the plurality of bridge die routing layers and above the inorganic substrate. In some embodiments, a second bridge die can be embedded in the dielectric layer. In some embodiments, the dielectric layer includes an inorganic dielectric. In some embodiments, the dielectric layer includes an organic dielectric. In some embodiments, a routing layer can be included over the dielectric layer and the first bridge die. In some embodiments, the routing layer includes a bonding surface to attach the interposer to a die. The bonding surface can be prepared for at least one of a flip chip bond, a thermocompression bond, or a hybrid bond. In some embodiments, the routing layer includes a bonding surface to hybrid bond the interposer to a die. In some embodiments, the dielectric layer includes a plurality of second vias. In some embodiments, the dielectric layer includes a plurality of damascene second vias. In some embodiments, a bonding surface can be included on an upper surface of the interposer, where the upper surface includes the dielectric layer. In some embodiments, the first bridge die includes a plurality of through substrate vias.

In some aspects, the techniques described herein relate to a microelectronic package, including an interposer, the interposer including an inorganic substrate, a first bridge die coupled to the inorganic substrate, a dielectric layer disposed over the inorganic substrate, and a first integrated circuit element bonded to the interposer. The first bridge die can include a width less than a width of the inorganic substrate, and the first bridge die can include a plurality of routing layers. An upper surface of the first bridge die can be coplanar with an upper surface of the dielectric layer.

In some embodiments, the inorganic substrate includes a base material of at least one of glass, silicon, quartz, and sapphire. In some embodiments, the first bridge die is directly bonded over the inorganic substrate. In some embodiments, the first bridge die includes a silicon layer. In some embodiments, the dielectric layer includes at least one of an oxide or a nitride. In some embodiments, the first bridge die is oriented face-down over the inorganic substrate. In some embodiments, the first bridge die is oriented face-up over the inorganic substrate. In some embodiments, a second integrated circuit element can be bonded to the interposer, where the first bridge die electrically connects the first integrated circuit element to the second integrated circuit element. In some embodiments, the interposer is hybrid bonded to the first integrated circuit element and the second integrated circuit element.

In some aspects, the techniques described herein relate to a method to form an interposer, the method including forming a plurality of first vias in an inorganic substrate, attaching a first bridge die to the inorganic substrate, and depositing a dielectric over the inorganic substrate, where the dielectric surrounds the first bridge die. The first bridge die can include a plurality of first routing layers and a base substrate layer.

In some embodiments, the method further includes planarizing the dielectric to remove at least a part of the base substrate layer. In some embodiments, attaching the first bridge die to the inorganic substrate includes directly bonding the first bridge die over the inorganic substrate. In some embodiments, the method further includes forming a plurality of second vias in the dielectric. In some embodiments, forming the plurality of second vias is conducted prior to the deposition of the dielectric. In some embodiments, forming the plurality of second vias is conducted after the deposition of the dielectric. In some embodiments, the method further includes forming a second routing layer over the dielectric and the first bridge die. In some embodiments, the method further includes forming a plurality of through substrate vias in the first bridge die.

In some aspects, the techniques described herein relate to a method of forming a microelectronic package, the method including bonding two or more integrated device dies to an interposer, where the interposer includes: an inorganic substrate having a plurality of vias; a dielectric layer disposed over a first surface of the inorganic substrate; and a first bridge die embedded in the dielectric layer, where the first bridge die includes a plurality of bridge die routing layers.

In some embodiments, the inorganic substrate includes glass. In some embodiments, the method further includes providing a routing layer between the two or more integrated device dies and the interposer. In some embodiments, bonding includes directly bonding first electrical contacts of the interposer with second electrical contacts of a first integrated circuit element of the two or more integrated device dies, and directly bonding a first dielectric of the interposer with a second dielectric of the first integrated circuit element. In some embodiments, the method further includes encapsulating the two or more integrated device dies with a mold. In some embodiments, the method further includes directly bonding the first bridge die to a routing layer over the inorganic substrate. In some embodiments, the method further includes forming a routing layer over the first surface of the inorganic substrate, and directly bonding the first bridge die to the routing layer.

In some aspects, the techniques described herein relate to an interposer assembly, including an interposer substrate, a bridge die mounted face down over the interposer substrate, and a first redistribution layer disposed over the bridge die, where the first redistribution layer is in electrical communication with the first pillar. The bridge die can include a plurality of routing layers and a first pillar extending upwardly from the plurality of routing layers toward a back side of the bridge die.

In some embodiments, the first redistribution layer includes an inorganic dielectric. In some embodiments, the inorganic dielectric is at least one of an oxide or a nitride. In some embodiments, the first pillar is between the first redistribution layer and a routing layer of the plurality of routing layers. In some embodiments, the bridge die includes a silicon substrate, where the silicon substrate is disposed between the first redistribution layer and the plurality of routing layers, and the first pillar extends through the silicon substrate. In some embodiments, the interposer substrate includes a base material of at least one of glass, silicon, quartz, and sapphire.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only and are not intended to limit the scope of the disclosure. Indeed, the apparatus, methods, and systems described herein may be embodied in a variety of other forms; furthermore, various omissions, substitutions, and changes in the form of the methods and systems described herein may be made without departing from the spirit of the disclosure. Any suitable combination of the elements and acts of the various embodiments described above can be combined to provide further embodiments. The accompanying claims and their equivalents are intended to cover such forms or modifications as would fall within the scope and spirit of the disclosure.

1.-17. (canceled)

18. An interposer, comprising:
a substrate, wherein the substrate comprises a plurality of first vias;
a dielectric layer on a first surface of the substrate; and
a first bridge die embedded in the dielectric layer, wherein the first bridge die comprises a plurality of bridge die routing layers, and wherein the first bridge die is directly bonded over the substrate.

19. The interposer of claim 18, wherein the substrate comprises an inorganic substrate.

20. The interposer of claim 19, wherein the first bridge die is hybrid bonded over the first surface of the inorganic substrate.

21. The interposer of claim 19, wherein the inorganic substrate comprises a routing layer, wherein the routing layer defines at least in part the first surface of the inorganic substrate.

22. (canceled)

23. The interposer of claim 19, wherein the first bridge die comprises a silicon substrate, wherein the plurality of bridge die routing layers is between the silicon substrate and the inorganic substrate.

24. The interposer of claim 19, wherein the first bridge die comprises a silicon substrate, wherein the silicon substrate is below the plurality of bridge die routing layers and above the inorganic substrate.

25. (canceled)

26. (canceled)

27. (canceled)

28. The interposer of claim 18, further comprising a routing layer over the dielectric layer and the first bridge die, wherein the routing layer comprises a bonding surface to attach the interposer to a die, wherein the bonding surface is prepared for at least one of a flip chip bond, a thermocompression bond, or a hybrid bond.

29. (canceled)

30. (canceled)

31. The interposer of claim 18, wherein the dielectric layer comprises a plurality of second vias.

32. (canceled)

33. (canceled)

34. (canceled)

35. A microelectronic package, comprising:
an interposer, the interposer comprising:
an inorganic substrate;
a first bridge die coupled to the inorganic substrate, wherein the first bridge die comprises a width less than a width of the inorganic substrate, and wherein the first bridge die comprises a plurality of routing layers;
a dielectric layer disposed over the inorganic substrate, wherein an upper surface of the first bridge die is coplanar with an upper surface of the dielectric layer; and
a first integrated circuit element bonded to the interposer.

36. The microelectronic package of claim 35, wherein the inorganic substrate comprises a base material of at least one of glass, silicon, quartz, and sapphire.

37. The microelectronic package of claim 35, wherein the first bridge die is directly bonded over the inorganic substrate.

38. (canceled)

39. The microelectronic package of claim 35, wherein the dielectric layer comprises at least one of an oxide or a nitride.

40. The microelectronic package of claim 35, wherein the first bridge die is oriented face-down over the inorganic substrate.

41. (canceled)

42. The microelectronic package of claim 35, further comprising a second integrated circuit element bonded to the interposer, wherein the first bridge die electrically connects the first integrated circuit element to the second integrated circuit element, and wherein the interposer is hybrid bonded to the first integrated circuit element and the second integrated circuit element.

43. (canceled)

44. A method to form an interposer, the method comprising:
forming a plurality of first vias in an inorganic substrate;
attaching a first bridge die to the inorganic substrate, wherein the first bridge die comprises a plurality of first routing layers and a base substrate layer; and
depositing a dielectric over the inorganic substrate, wherein the dielectric surrounds the first bridge die.

45. The method of claim 44, further comprising planarizing the dielectric to remove at least a part of the base substrate layer.

46. The method of claim 44, wherein attaching the first bridge die to the inorganic substrate comprises directly bonding the first bridge die over the inorganic substrate.

47. The method of claim 44, further comprising forming a plurality of second vias in the dielectric.

48. (canceled)

49. (canceled)

50. The method of claim 44, further comprising forming a second routing layer over the dielectric and the first bridge die.

51. The method of claim 44, further comprising forming a plurality of through substrate vias in the first bridge die.

52.-64. (canceled)
